(19) United States
(12) Patent Application Publication
(10) Pub. No.: US 2015/0155471 A1
(43) Pub. Date: Jun. 4, 2015

(54) POWER GENERATING ELEMENT

(71) Applicant: MITSUMI ELECTRIC CO., LTD., Tokyo (JP)

(72) Inventors: Kenichi Furukawa, Sagamihara-shi (JP); Takayuki Numakunai, Tama-shi (JP)

(73) Assignee: Mitsumi Electric Co., Ltd., Tama-Shi, Tokyo (JP)

(21) Appl. No.: 14/401,505

(22) PCT Filed: Jul. 22, 2013
(86) PCT No.: PCT/JP2013/069734

§ 371 Date: Nov. 14, 2014

(30) Foreign Application Priority Data
Jul. 23, 2012 (JP) 2012-162321

(51) Int. Cl. H01L 41/12

(52) U.S. Cl. CPC H01L 41/125

(57) ABSTRACT

A power generating element includes two pillar-shaped magnetostrictive bodies through which lines of magnetic force pass in an axial direction thereof, each of the two pillar-shaped magnetostrictive bodies formed of a magnetostrictive material; a pressing body having a pressing part provided so as to press the magnetostrictive body when the pressing part is pivotally moved and a rod part for pivotally moving the pressing part; and a coil provided so that the lines of magnetic force pass through in an axial direction thereof and in which a voltage is generated on the basis of a variation of density of the lines of magnetic force. The power generating element is configured to vary the density of the lines of magnetic force when the pressing part is pivotally moved due to a pivotal movement of the rod part around a pivotal center and then the magnetostrictive body is pressed and compressed by the pressing part.

### TECHNICAL FIELD

The present invention relates to a power generating element.

### BACKGROUND ART

In recent years, a power generating element which can generate electric power by utilizing a variation of magnetic permeability of a magnetostrictive body formed of a magnetostrictive material has been developed (for example, see patent document 1).

For example, the power generating element includes a pair of magnetostrictive rods arranged in parallel with each other, a connecting yoke connecting the pair of magnetostrictive rods, coils provided so as to respectively surround the magnetostrictive rods, a permanent magnet for applying a bias magnetic field to the magnetostrictive rods and a back yoke. In this power generating element, when external force is applied to the connecting yoke in a direction perpendicular to an axial direction of the magnetostrictive rods, one of the magnetostrictive rods is deformed so as to expand (be stretched) in the axial direction thereof and the other of the magnetostrictive rods is deformed so as to contract (be compressed) in the axial direction thereof. At the time of expansion and compression of the magnetostrictive rods, density of lines of magnetic force (magnetic flux density) passing through each of the magnetostrictive rods varies. In other words, the density of the lines of magnetic force passing through each of the coils varies due to the deformations of the magnetostrictive rods. As a result of the variation of the density of the lines of magnetic force, a voltage is generated in each coil.

Since the power generating element described above generates the electric power by utilizing the expansion and the compression of the magnetostrictive rods, strong connecting force between each of the magnetostrictive rods and the connecting yoke is required. In particular, the strong connecting force is especially required when one of the magnetostrictive rods is expanded. Further, since each of the magnetostrictive rods having a relatively long length is used in the power generating element, a used amount of the high-cost magnetostrictive material for forming the magnetostrictive rods increases.

Further, from the point of view of improving power generating efficiency, it is preferable that only tensile stress (extensional stress) is alternately caused in one of the magnetostrictive rods and only compressive stress is alternately caused in the other of the magnetostrictive rods in the power generating element described above. However, when stress caused in each magnetostrictive rod is analyzed actually, it is observed that both the tensile stress and the compressive stress are simultaneously caused in one magnetostrictive rod. Namely, it is difficult to cause uniform stress (that is only one of the tensile stress and the compressive stress) in one magnetostrictive rod used in the power generating element.

### RELATED ART DOCUMENT

### Patent Document

Patent document 1: WO 2011/158473

### SUMMARY OF THE INVENTION

The present invention has been made in view of the problems mentioned above. Accordingly, it is an object of the present invention to provide a power generating element which has a relatively simple configuration and can efficiently generate electric power.

In order to achieve the object described above, the present invention includes the following features (1) to (12).

(1) A power generating element comprising:

at least one pillar-shaped magnetostrictive body through which lines of magnetic force pass in an axial direction thereof, the at least one magnetostrictive body formed of a magnetostrictive material;

a pressing body having a pressing part provided so as to press the magnetostrictive body when the pressing part is pivotally moved and a rod part for pivotally moving the pressing part; and

a coil provided so that the lines of magnetic force pass through the coil in an axial direction thereof and in which a voltage is generated on the basis of a variation of density of the lines of magnetic force,

wherein the power generating element is configured to vary the density of the lines of magnetic force when the pressing part is pivotally moved due to a pivotal movement of the rod part around a pivotal center and then the magnetostrictive body is pressed and compressed by the pressing part.

(2) The power generating element described in above (1), wherein the pressing body has a central part which can be pivotally moved around the pivotal center, and

wherein the pressing part is provided on an area of the central part so as to laterally protrude from the central part, and the rod part is connected with the central part at another area differing from the area of the central part on which the pressing part is provided.

(3) The power generating element described in above (1) or (2), wherein the pressing part has a holding structure for holding the magnetostrictive body.

(4) The power generating element described in any one of above (1) to (3), wherein the at least one magnetostrictive body includes two magnetostrictive bodies respectively provided on both sides of the central part so that the two magnetostrictive bodies are alternately pressed by the pressing part.

(5) The power generating element described in any one of above (1) to (4), wherein the coil is provided on an outer peripheral side of the magnetostrictive body so as to surround the magnetostrictive body.

(6) The power generating element described in any one of above (1) to (5), wherein the magnetostrictive material contains an iron-gallium based alloy as a major component thereof.

(7) The power generating element described in any one of above (1) to (6), wherein a Young's modulus of the magnetostrictive material is in the range of 40 to 100 GPa.

(8) The power generating element described in any one of above (1) to (7), wherein the pressing part is formed of a magnetic material and provided so as to press the magnetostrictive body in the axial direction of the magnetostrictive body.

(9) The power generating element described in above (8), further comprising,

a magnet for generating the lines of magnetic force; and

a loop forming body for forming a loop in cooperation with at least the magnetostrictive body and the pressing part so that the lines of magnetic force generated from the magnet flow in the loop and return to the magnet, the loop forming body formed of a magnetic material.

(10) The power generating element described in above (9), wherein the coil is provided in a middle of the loop forming body so as to surround the loop forming body.

(11) The power generating element described in above (9) or (10), wherein the magnet is provided between the magnetostrictive body and the loop forming body.

(12) The power generating element described in any one of above (9) to (11), wherein the loop forming body has a holding structure for holding the magnet.

### Effect of the Invention

According to the present invention, it becomes unnecessary to strongly connect the components of the power generating element with each other because the power generating element can generate electric power only by compressing the magnetostrictive body. Thus, it is possible to provide the power generating element which has the relatively simple configuration and can efficiently generate electric power.

### BRIEF DESCRIPTION OF THE DRAWINGS

FIG. 1 is a perspective view showing a power generating element according to a first embodiment of the present invention.

FIG. 2 is an exploded perspective view showing the power generating element shown in FIG. 1.

FIG. 3 is a perspective view showing the vicinity of a center of the power generating element shown in FIG. 1.

FIG. 4 is an enlarged view showing the vicinity of a magnetostrictive body of the power generating element shown in FIG. 1.

FIG. 5 is an enlarged view showing the vicinity of a permanent magnet of the power generating element shown in FIG. 1.

FIG. 6 is a cross-sectional view taken along an A-A line shown in FIG. 1.

FIG. 7 is an analysis diagram illustrating an analysis result of stress caused in the magnetostrictive body in a case where a point of application for pressing the magnetostrictive doby is located between a fulcrum of a rod part and a point of force for applying force to the rod part.

FIG. 8 is an analysis diagram illustrating an analysis result of stress caused in the magnetostrictive body of the power generating element shown in FIG. 1.

FIG. 9 is an analysis diagram illustrating an analysis result of stress caused in the magnetostrictive body of the power generating element shown in FIG. 1.

FIG. 10 is a perspective view showing a power generating element according to a second embodiment of the present invention.

FIG. 11 is a cross-sectional view taken along a B-B line shown in FIG. 10.

FIG. 12 is a perspective view showing a power generating element according to a third embodiment of the present invention.

FIG. 13 is a perspective view showing the vicinity of a center of the power generating element shown in FIG. 12.

FIG. 14 is an enlarged partial cross-sectional view showing the vicinity of a center of a power generating element according to a fourth embodiment of the present invention.

FIG. 15 is a perspective view showing the vicinity of a center of a power generating element according to a fifth embodiment of the present invention.

FIG. 16 is a cross-sectional view showing the vicinity of a center of a power generating element according to a sixth embodiment of the present invention.

### DETAILED DESCRIPTION OF THE PREFERRED EMBODIMENTS

Hereinafter, a power generating element of the present invention will be described in detail with reference to preferred embodiments shown in the accompanying drawings.

### First Embodiment

First, description will be given to a power generating element according to a first embodiment of the present invention.

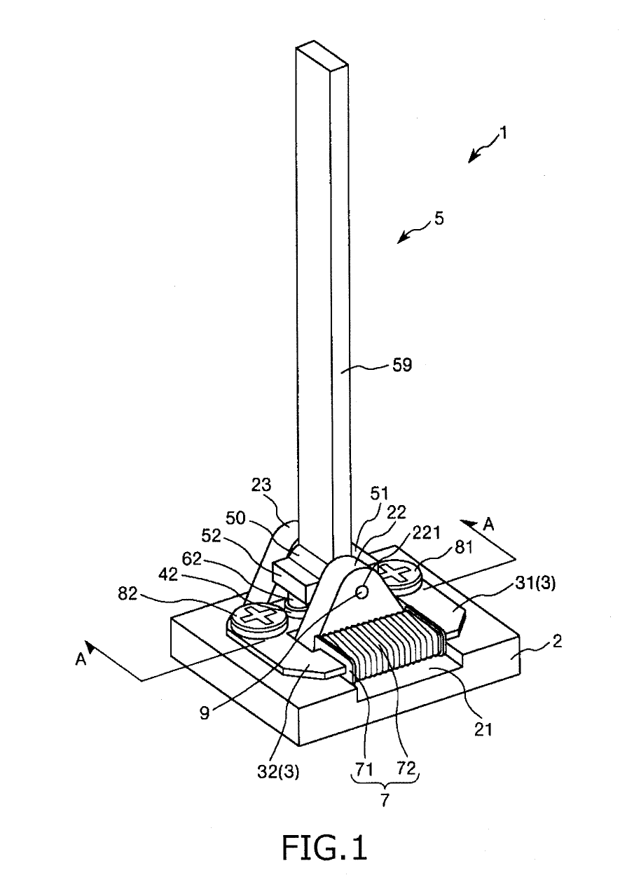

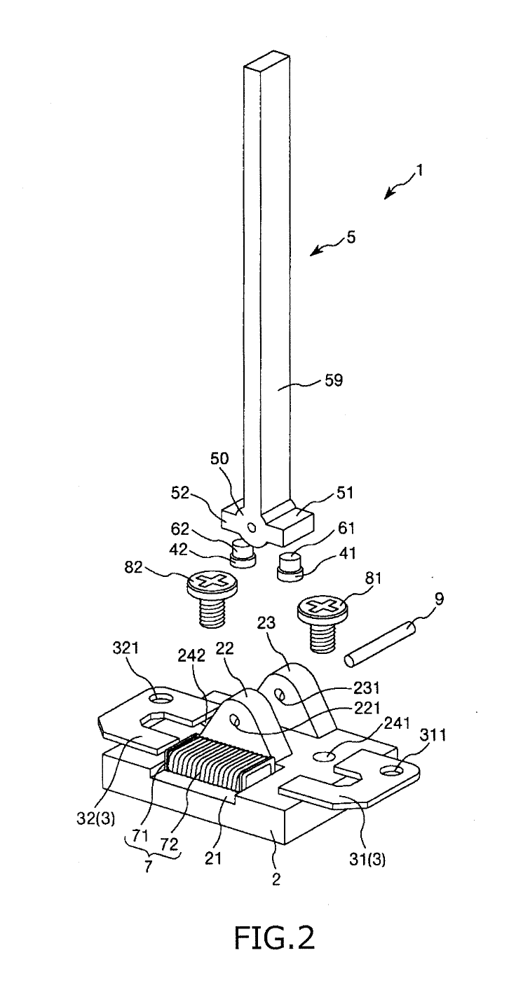

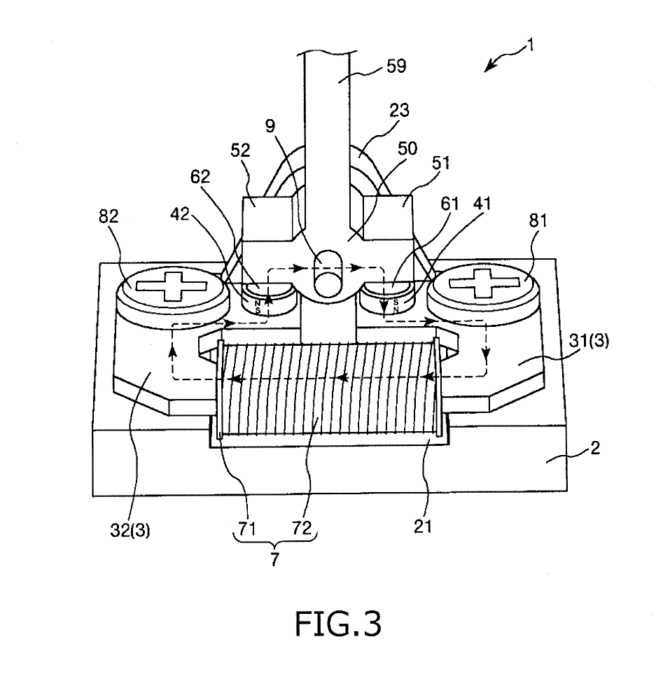

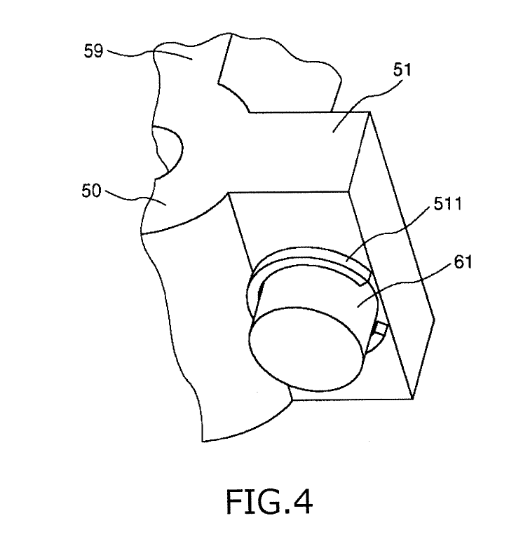

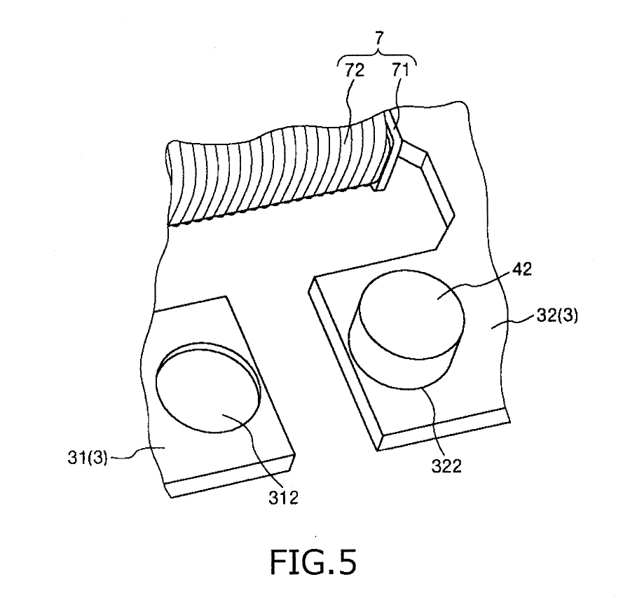

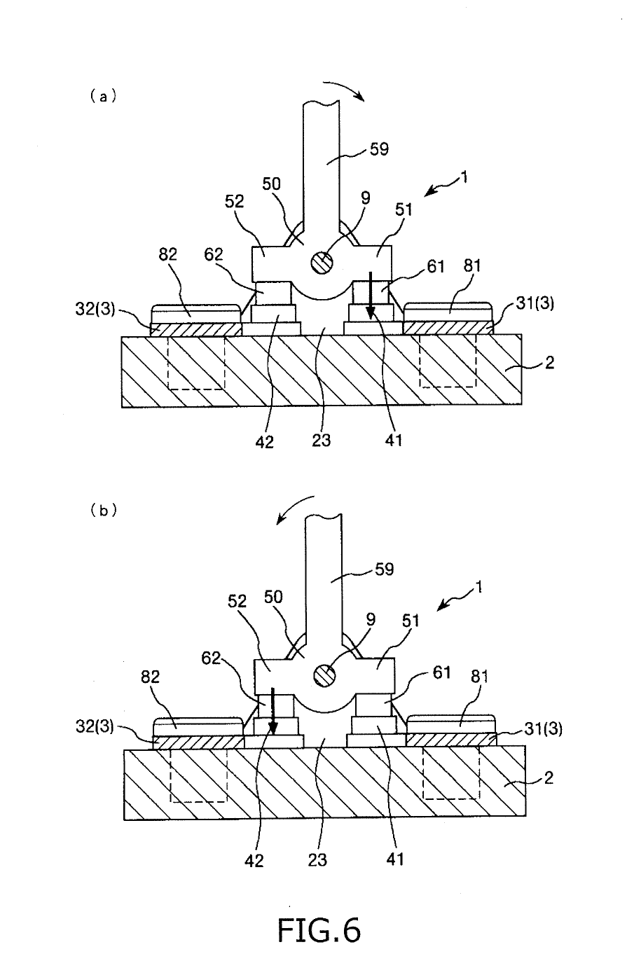

FIG. 1 is a perspective view showing the power generating element according to the first embodiment of the present invention. FIG. 2 is an exploded perspective view showing the power generating element shown in FIG. 1. FIG. 3 is a perspective view showing the vicinity of a center of the power generating element shown in FIG. 1. FIG. 4 is an enlarged view showing the vicinity of a magnetostrictive body of the power generating element shown in FIG. 1. FIG. 5 is an enlarged view showing the vicinity of a permanent magnet of the power generating element shown in FIG. 1. FIG. 6 is a cross-sectional view taken along an A-A line shown in FIG. 1.

Hereinafter, an upper side in each of FIGS. 1 to 6 is referred to as “upper” or “upper side” and a lower side in each of FIGS. 1 to 6 is referred to as “lower” or “lower side”. Further, a front side of the paper in each of FIGS. 1 to 3 and 6 is referred to as “front” or “front side” and a rear side of the paper in each of FIGS. 1 to 3 and 6 is referred to as “back” or “back side”. Furthermore, a right side in each of FIGS. 1 to 3 and 6 is referred to as “right” or “right side” and a left side in each of FIGS. 1 to 3 and 6 is referred to as “left” or “left side”.

A power generating element 1 shown in FIGS. 1 and 2 has a base body 2, a yoke 3 provided on the base body 2, a pair of permanent magnets 41, 42 provided on the yoke 3, a pressing body 5 provided so as to be capable of pivotally moving with respect to the base body 2, a pair of magnetostrictive bodies 61, 62 provided on the pressing body 5 so as to respectively correspond to the permanent magnets 41, 42 and a coil 7 in which the yoke 3 is inserted.

In the power generating element 1 having such a configuration, one of the magnetostrictive bodies 61, 62 is compressed by the pressing body 5 and the permanent magnets 41, 42 in an axial direction of the magnetostrictive bodies 61, 62 when the pressing body 5 is pivotally moved around a pivotal center, that is, when the pressing body is pivotally moved in a right-left direction (a clockwise direction or a counterclockwise direction) as shown in FIG. 6. At this time, magnetic permeability of the compressed one of the magnetostrictive bodies 61, 62 varies due to an inverse magnetostrictive effect. This variation of the magnetic permeability leads to a variation of density of lines of magnetic force passing through the magnetostrictive bodies 61, 62 (that is, the lines of magnetic force passing through the coil 7), and thereby generating a voltage in the coil 7.

Hereinafter, description will be given to a configuration of each component of the power generating element 1.

<<Base Body 2>>

The base body 2 serves as a component for supporting other components of the power generating element 1. The base body 2 has a plate-like shape. In addition to this function, the base body 2 is used for fixing the power generating element 1 to a case (housing) or the like. A concave portion 21 is formed on a front side of an upper surface of the base body 2. The coil 7 is placed in the concave portion 21.

A pair of plate-like bearings 22, 23 is formed on a back side of the upper surface of the base body 2 so as to upwardly protrude. Through-holes 221, 231 are respectively formed in the plate-like bearings 22, 23 so as to pass through the plate-like bearings 22, 23 in a thickness direction thereof. Further, the bearings 22, 23 are arranged so as to face to each other along a front-back direction of the base body 2. Thus, by inserting a shaft 9 into the through-holes 221, 231 and a central part 50 of the pressing body 5 (which will be described below), it is possible to pivotally move the pressing body 5 with respect to the base body 2 in the right-left direction in FIG. 3.

Further, a pair of threaded holes 241, 242 is formed on both right and left sides on the upper surface of the base body 2 through the bearings 22, 23. Screws 81, 82 are respectively screwed into the threaded holes 241, 242 to fix the yoke 3 on the base body 2.

Examples of a constituent material for the base body 2 include a metallic material, a semiconductor material, a ceramic material, a resin material and a combination of two or more of these materials. On the upper surface of the base body 2, the plate-like yoke 3 formed of a magnetic material is fixed.

<<Yoke 3>>

In this embodiment, the yoke 3 is constituted of a right side piece 31 and a left side piece 32. A shape of each piece 31, 32 is similar to a shape obtained by bending (or curving) an elongated plate at the middle portion of a longitudinal direction thereof. Namely, each of the pieces 31, 32 has an approximate C shape in planar view thereof.

As shown in FIGS. 2 and 3, one end of each of the pieces 31, 32 is inserted into an inner cavity of the coil 7 (bobbin 71). In this state, the one end of the right side piece 31 inserted into the inner cavity of the coil 7 makes contact with the one end of the left side piece 32 inserted into the inner cavity of the coil 7. On the other hand, the other end of the right side piece 31 does not contact with the other end of the left side piece 32 as shown in FIGS. 3 and 6.

In the middle portions of the pieces 31, 32, through-holes 311, 321 are respectively formed so as to pass through the pieces 31, 32 in a thickness direction thereof. By respectively inserting and screwing threaded portions of the screws 81, 82 into the threaded holes 241, 242 of the base body 2 through the through-holes 311, 321, the yoke 3 (the right side piece 31 and the left side piece 32) is fixed on the base body 2.

As shown in FIG. 5, concave portions 312, 322 are respectively formed on upper surfaces of the other ends of the pieces 31, 32. The concave portions 312, 322 respectively hold the permanent magnets 41, 42. Namely, each of the concave portions 312, 322 constitutes a holding structure for holding each of the permanent magnets 41, 42.

Examples of the magnetic material for, forming the yoke 3 include a pure iron (e.g., “JIS SUY”), a soft iron, a carbon steel, a magnetic steel (silicon steel), a high-speed tool steel, a structural steel (e.g., “JIS SS400”), a stainless permalloy and a combination of two or more of these magnetic materials.

The permanent magnets 41, 42 are respectively fixed to the concave portions 312, 322 with, for example, an engagement method (fitting method), a welding method, a bonding method using an adhesive or the like.

<<Permanent magnets 41, 42>>

The permanent magnets 41, 42 are respectively arranged just below the magnetostrictive bodies 61, 62 to apply a bias magnetic field to the magnetostrictive bodies 61, 62.

As shown in FIG. 3, the permanent magnet 41 is provided so that its north pole faces to a side of the yoke 3 and its south pole faces to a side of the magnetostrictive body 61. The permanent magnet 42 is provided so that its south pole faces to a side of the yoke 3 and its north pole faces to a side of the magnetostrictive body 62. By arranging the permanent magnets 41, 42 in this manner, it is possible to form a loop (a magnetic field loop circulating in the clockwise direction) in which the lines of magnetic force generated from the permanent magnets 41, 42 flow. In the loop, the lines of magnetic force generated from the permanent magnets 41, 42 pass through the magnetostrictive bodies 61, 62, a lower end (the central part 50 and pressing parts 51, 52) of the pressing body 5 and the yoke (loop forming body) 3 and return to the permanent magnets 41, 42.

For example, an alnico magnet, a ferrite magnet, a neodymium magnet, a samarium-cobalt magnet, a magnet (bonded magnet) obtained by molding a composite material prepared by pulverizing and mixing at least one of these magnets with a resin material or a rubber material, or the like may be used as the permanent magnets 41, 42.

The pressing body 5 is supported by the base body 2 in a state that the pressing body 5 can be pivotally moved. In this state, the pressing body 5 is positioned above the permanent magnets 41, 42.

<<Pressing body 5>>

The pressing body 5 is constituted of the cylindrical central part 50, the pair of pressing parts 51, 52 provided on lateral areas of the central part 50 so as to laterally protrude from the central part 50 and a rod part 59 connected with the central part 50. The shaft 9 is inserted into the through-holes 221, 231 of the bearings 22, 23 and a through-hole (central cavity) of the central part 50. Since the shaft 9 serves as the pivotal center (axis), the pressing body 5 can be pivotally moved with respect to the base body 2.

Although the shaft 9 and the central part 50 are formed as separated parts in this embodiment, the shaft 9 and the central part 50 may be integrally formed. In this case, small-diameter cylinders may be formed on a front end surface and a back end surface of the cylindrical central part 50. The small-diameter cylinders serve as the shaft 9 to be inserted into the through-holes 221, 231. Alternatively, small-diameter cylinders may be formed on inner peripheral surfaces of the bearings 22, 23 so as to laterally protrude. The small-diameter cylinders serve as the shaft 9 to be inserted into the through-hole of the cylindrical central part 50.

The pair of pressing parts 51, 52 is integrally formed with the central part 50. The pressing parts 51, 52 are provided so as to face to each other through the shaft 9. The pressing part 51 has a plate-like shape. As shown in FIG. 4, a rib 511 having a C shape is formed on a lower surface of the pressing part 51. The magnetostrictive body 61 is held inside the rib 511. Namely, the rib 511 constitutes a holding structure for holding the magnetostrictive body 61. Similarly, the pressing part 52 has the same configuration as the pressing part 51. Namely, the magnetostrictive body 62 is held on a lower surface of the pressing part 52.

The rod part 59 serves as a component for applying external force or vibration to the pressing body 5. The rod part 59 is connected to an outer peripheral surface of the central part 50 at another area differing from the lateral areas on which the pair of pressing parts 51, 52 is provided. In this embodiment, an angle formed by the other area and the lateral areas on which the pair of pressing parts 51, 52 is provided is about 90 degree (that is, the angle formed by the rod part 59 and one of the pressing parts 51, 52 is about 90 degree). When external force toward the right or left direction in FIG. 6 or vibration in the right-left direction in FIG. 6 is applied to the rod part 59, the rod part 59 is pivotally moved in the right-left direction in FIG. 6 around the shaft 9 (pivotal center). This makes it possible to pivotally move the pressing parts 51, 52.

As described above, in this embodiment, the lines of magnetic force pass through the lower end of the pressing body 5. For passing the lines of magnetic force through the lower end of the pressing body 5, at least the central part 50 and the pressing parts 51, 52 are formed of, for example, the same magnetic material as the constituent material for the yoke 3. Further, the rod part 59 may be integrally formed with the central part 50 and the pressing parts 51, 52 by using a magnetic material. Alternatively, the rod part 59 may be formed separately from the central part 50 and the pressing parts 51, 52 by using a nonmagnetic material.

The nonmagnetic material for the rod part 59 is not particularly limited to a specific kind. Examples of the nonmagnetic material for the rod part 59 include a metallic material, a semiconductor material, a ceramic material, a resin material and a combination of two or more of these materials. In the case of using the resin material as the nonmagnetic material for the rod part 59, it is preferred that filler is added into the resin material. Among them, a nonmagnetic material containing a metallic material as a major component thereof is preferably used as the nonmagnetic material for the rod part 59. Further, a nonmagnetic material containing at least one of aluminum, magnesium, zinc, copper and an alloy containing at least one of these materials as a major component thereof is more preferably used as the nonmagnetic material for the rod part 59.

A size of each of the pressing parts 51, 52 is appropriately set depending on the constituent material for the pressing parts 51, 52, a size of each of the magnetostrictive bodies 61, 62 and the like. The size of each of the pressing parts 51, 52 is not particularly limited to a specific size, but a thickness of each of the pressing parts 51, 52 is preferably in the range of about 0.5 to 3 mm, and more preferably in the range of about 1 to 2.5 mm. Further, a width (length in the right-left direction) of each of the pressing parts 51, 52 is preferably in the range of about 1 to 5 mm, and more preferably in the range of about 1.5 to 3.5 mm.

In addition, a size of the rod part 59 is appropriately set depending on the constituent material for the rod part 59 and the like. The size of the rod part 59 is not particularly limited to a specific value, but a thickness (length in the right-left direction) of the rod part 59 is preferably in the range of about 0.5 to 3 mm, and more preferably in the range of about 1 to 2.5 mm. Further, a width (length in the front-back direction) of the rod part 59 is preferably in the range of about 2 to 7 mm, and more preferably in the range of 3 to 6 mm. Furthermore, a length of the rod part 59 is preferably in the range of 10 to 70 mm, and more preferably in the range of 20 to 60 mm.

The magnetostrictive bodies 61, 62 are respectively fixed to the pressing parts 51, 52 (ribs 511) of the pressing body 5 as described above with, for example, an engagement method (fitting method), a welding method, a bonding method using an adhesive or the like.

<<Magnetostrictive bodies 61, 62>>

Each of the magnetostrictive bodies 61, 62 is formed of a magnetostrictive material and arranged so that a direction in which magnetization is easily generated (an easy magnetization direction) becomes the vertical direction (axial direction) thereof. Each of the magnetostrictive bodies 61, 62 has a cylindrical (pillar) shape having a relatively small thickness. Each of the magnetostrictive bodies 61, 62 is arranged in a state that the lines of magnetic force can pass through the magnetostrictive bodies 61, 62 in the axial direction thereof.

The two magnetostrictive bodies 61, 62 are provided on both right and left sides of the central part of the pressing body 5 so as to respectively correspond to the permanent magnets 41, 42. With such a configuration, the two magnetostrictive bodies 61, 62 are alternately pressed by the corresponding pressing parts 51, 52.

A horizontal cross-sectional area (cross-sectional area in a direction substantially perpendicular to the axial direction of the magnetostrictive bodies 61, 62) of each of the magnetostrictive bodies 61, 62 is not particularly limited to a specific value, but preferably in the range of about 1 to 40 mm², and more preferably in the range of about 2 to 20 mm². By setting the horizontal cross-sectional area of each of the magnetostrictive bodies 61, 62 to fall within the above range, it is possible to sufficiently pass the lines of magnetic force in the thickness direction of each of the magnetostrictive bodies 61, 62. Further, it is possible to reduce a used amount of the high-cost magnetostrictive material for the power generating element 1 and obtain the power generating element 1 which can maximally provide its effects.

A thickness (length) of each of the magnetostrictive bodies 61, 62 is not particularly limited to a specific value, but is preferably in the range of about 0.1 to 2 mm, and more preferably in the range of about 0.5 to 1.5 mm. By setting the length of each of the magnetostrictive bodies 61, 62 to fall within the above range, it is possible to cause more uniform compressive stress in each of the magnetostrictive bodies 61, 62, and thereby improving power generating efficiency of the power generating element 1 (coil 7).

A Young's modulus of the magnetostrictive material is preferably in the range of about 40 to 100 GPa, more preferably in the range of about 50 to 90 GPa, and even more preferably in the range of about 60 to 80 GPa. By forming each of the magnetostrictive bodies 61, 62 with the magnetostrictive material having the above Young's modulus, it is possible to more significantly compress each of the magnetostrictive bodies 61, 62. This makes it possible to more drastically vary the magnetic permeability of each of the magnetostrictive bodies 61, 62, and thereby further improving the power generating efficiency of the power generating element 1 (coil 7).

The magnetostrictive material having the above Young's modulus is not particularly limited to a specific kind. Examples of such a magnetostrictive material include an iron-gallium based alloy, an iron-cobalt based alloy, an iron-nickel based alloy and a combination of two or more of these materials. Among them, a magnetostrictive material containing an iron-gallium based alloy (having a Young's modulus of about 70 GPa) as a main component thereof is preferably used. A Young's modulus of such a magnetostrictive material containing the iron-gallium based alloy can be adjusted to fall within the above range with ease.

Further, it is preferred that the magnetostrictive material as described above contains at least one rare-earth metal such as Y, Pr, Sm, Tb, Dy, Ho, Er and Tm. By using the magnetostrictive material containing such a rare-earth metal, it is possible to more significantly increase the variation of the magnetic permeability of the magnetostrictive bodies 61, 62.

The coil 7 is provided in the middle way of the axial direction of the yoke (loop forming body) 3, that is, in the middle way of the magnetic field loop so as to surround the yoke 3.

<<Coil 7>>

On the basis of the variation of the density of the lines of magnetic force (magnetic flux density) caused by the variation of the magnetic permeability of one of the magnetostrictive bodies 61, 62, the voltage is generated in the coil 7. The coil 7 is constituted of a square cylindrical bobbin 71 provided on an outer peripheral side of the yoke 3 so as to surround the yoke 3 and a wire 72 wound around the bobbin 71. The coil 7 is placed in the concave portion 21 of the base body 2.

With such a configuration of the coil 7, it is possible to make design (layout) of the power generating element 1 free from a volume (size) restriction of the coil 7. This makes it possible to expand the range of choice for the winding number of the wire 72 constituting the coil 7, a cross-sectional area (wire diameter) of the wire 72 and the like depending on the power generating efficiency, load impedance, a targeted voltage value, a targeted current value and the like.

For example, the same material as the constituent material for the rod part 59 may be used as a constituent material for the bobbin 71. Further, the type of the wire 72 is not particularly limited to a specific type. Examples of the type of the wire 72 include a wire obtained by covering a copper base line with an insulating layer, a wire obtained by covering a copper base line with an insulating layer to which an adhesive (fusion) function is imparted and a combination of two or more of these wires.

The winding number of the wire 72 is appropriately set depending on the cross-sectional area and the like of the wire 72. The winding number of the wire 72 is not particularly limited to a specific number, but is preferably in the range of about 100 to 500, and more preferably in the range of about 150 to 450. Further, the cross-sectional area of the wire 72 is preferably in the range of about 5×10⁻⁴ to 0.126 mm², and more preferably in the range of about 2×10⁻³ to 0.03 mm².

A cross-sectional shape of the wire 72 may be any shape. Examples of the cross-sectional shape of the wire 72 include a polygonal shape such as a triangular shape, a square shape, a rectangular shape and a hexagonal shape; a circular shape and an elliptical shape.

In the power generating element 1 as described above, when the rod part 59 of the pressing body 5 is leaned toward the right side as shown in FIG. 6(a), that is, when the rod part 59 is pivotally moved around the shaft 9 in the right direction, the pressing part 51 is moved toward the lower side and moved closer to the permanent magnet 41. Due to this movement, the magnetostrictive body 61 is compressed in the axial direction thereof by the pressing part 51 and the permanent magnet 41. As a result, the magnetic permeability of the magnetostrictive body 61 is varied due to the inverse magnetostrictive effect. This variation of the magnetic permeability of the magnetostrictive body 61 leads to the variation of the density of the lines of magnetic force passing through the magnetostrictive body 61 (the density of the lines of magnetic force passing through the inner cavity of the coil 7 in the axial direction thereof), and thereby generating the voltage in the coil 7. At this time, the pressing part 52 is moved in a direction leaving from the permanent magnet 42 (toward the upper side) together with the magnetostrictive body 62 held (fixed) by the pressing part 52. However, the magnetostrictive body 62 is not pulled (stretched) so as to expand because the magnetostrictive body 62 is not fixed to the permanent magnet 42.

On the other hand, when the rod part 59 of the pressing body 5 is leaned toward the left side as shown in FIG. 6(b), that is, when the rod part 59 is pivotally moved around the shaft 9 in the left direction, the pressing part 52 is moved toward the lower side and moved closer to the permanent magnet 42. Due to this movement, the magnetostrictive body 62 is compressed in the axial direction thereof by the pressing part 52 and the permanent magnet 42. As a result, the magnetic permeability of the magnetostrictive body 62 is varied due to the inverse magnetostrictive effect. This variation of the magnetic permeability of the magnetostrictive body 62 leads to the variation of the density of the lines of magnetic force passing through the magnetostrictive body 62 (the density of the lines of magnetic force passing through the inner cavity of the coil 7 in the axial direction thereof), and thereby generating the voltage in the coil 7. At this time, the pressing part 51 is moved in a direction leaving from the permanent magnet 41 (toward the upper side) together with the magnetostrictive body 61 held (fixed) by the pressing part 51. However, the magnetostrictive body 61 is not pulled (stretched) so as to expand because the magnetostrictive body 61 is not fixed to the permanent magnet 41.

As described above, in the present invention, the power generation is achieved only by compressing the magnetostrictive bodies 61, 62 without expanding the magnetostrictive bodies 61, 62. Thus, strong fixations between the magnetostrictive bodies 61, 62 and other components (in this embodiment, the pressing body 5 or each permanent magnet 41, 42) for expanding the magnetostrictive bodies 61, 62 become unnecessary. Therefore, it is possible to simplify the configuration of each component, and thereby reducing the production cost of the power generating element 1 and saving time and effort for assembling the power generating element 1.

Further, since the pressing parts 51, 52 respectively compress the corresponding magnetostrictive bodies 61, 62 by utilizing the principle of leverage, it is possible to add relatively large compressive stress to each of the magnetostrictive bodies 61, 62 even in the case where force (external force) applied to an upper end (open end) of the rod part 59 is small.

Furthermore, since the inverse magnetostrictive effect is exhibited by compressing the magnetostrictive bodies 61, 62, it is possible to effectively exhibited the sufficient inverse magnetostrictive effect even in the case where the sizes of the magnetostrictive bodies 61, 62 are smaller. This makes it possible to increase a contribution ratio of the magnetostrictive material per unit volume to the power generation, and thereby reducing the used amount of the high-cost magnetostrictive material. This contributes to weight reduction, miniaturization and cost reduction of the power generating element 1.

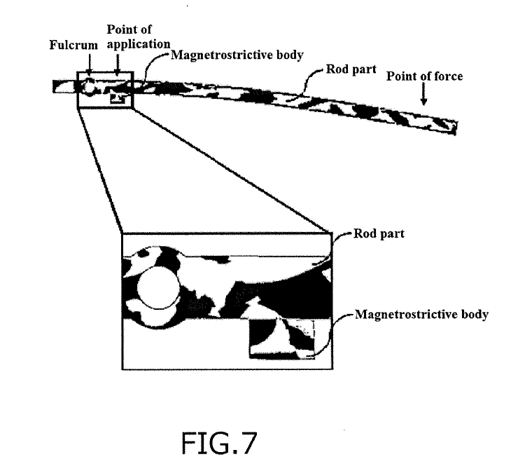

Ina case where a point of application for pressing the magnetostrictive body is located between a fulcrum of the rod part and a point of force for applying force to the rod part as shown in FIG. 7, a load caused by deformation (deflection) of the rod part is transferred to the magnetostrictive body depending on the magnitude of the external force or the vibration applied to the rod part, a position at which the external force or the vibration is applied, a direction in which the external force or the vibration is applied, the constituent material for the rod part or the like. Due to the load transferred to the rod part, there is a case where it is impossible to cause uniform compressive stress in the magnetostrictive body.

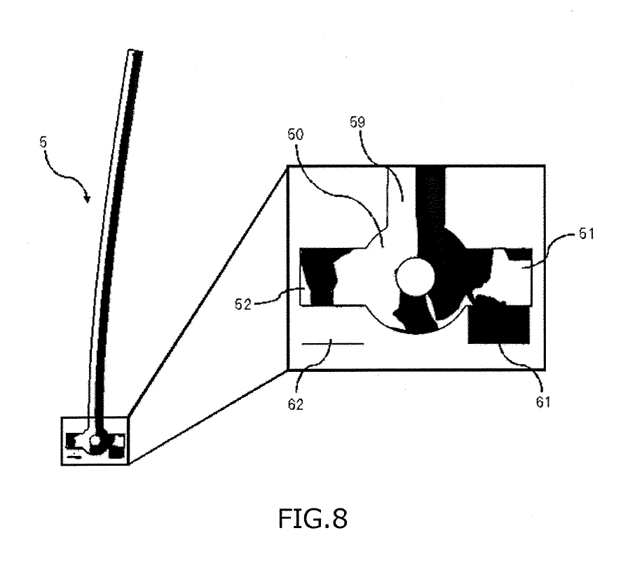

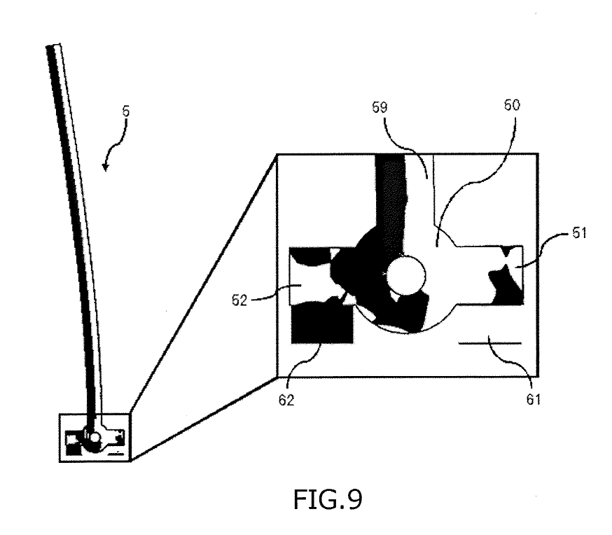

In contrast, in this embodiment, the pressing parts 51, 52 (a point of application) for pressing each of the magnetostrictive bodies 61, 62 are not located between the pivotal center (fulcrum) of the pressing body 5 and the open end (a point of force) for applying force to the rod part 59. Thus, it is possible to prevent the load caused by the deformation (deflection) of the rod part 59 from being transferred to each of the magnetostrictive bodies 61, 62 when each of the magnetostrictive bodies 61, 62 is compressed by each of the pressing parts 51, 52. In this case, a main component of the load applied to the magnetostrictive body 61 when the rod part 59 is leaned toward the right side is a load toward the lower side. This makes it possible to cause uniform compressive stress in the magnetostrictive body 61 (see FIG. 6(a) and FIG. 8). On the other hand, a main component of the load applied to the magnetostrictive body 62 when the rod part 59 of the pressing body 5 is leaned toward the left side is also a load toward the lower side. This makes it possible to cause uniform compressive stress in the magnetostrictive body 62 (see FIG. 6 (b) and FIG. 9). Therefore, it is possible to effectively exhibited the sufficient inverse magnetostrictive effect.

Further, the size, the shape and the weight of the rod part 59 can be appropriately adjusted. For example, by shortening the length of the rod part 59, it is possible to reduce the height (thickness) of the power generating element 1. Furthermore, for example, by modifying the shape of the upper end of the rod part 59, it is possible to connect a cam mechanism or a weight unit to the rod part 59. A power generation amount of the power generating element 1 is not particularly limited to a specific value, but is preferably in the range of about 100 to 1400 μJ. If the power generation amount of the power generating element 1 is in the above range, it is possible to efficiently use the power generating element 1 for a wireless switch for house lighting, a home security system or the like (which will be described below) in combination with a wireless communication device.

### Second Embodiment

Next, description will be given to a power generating element according to a second embodiment of the present invention.

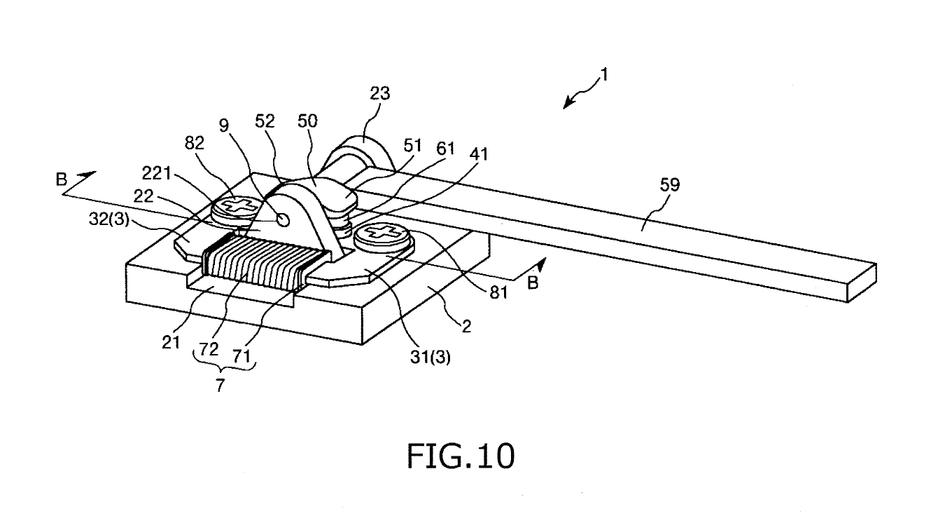

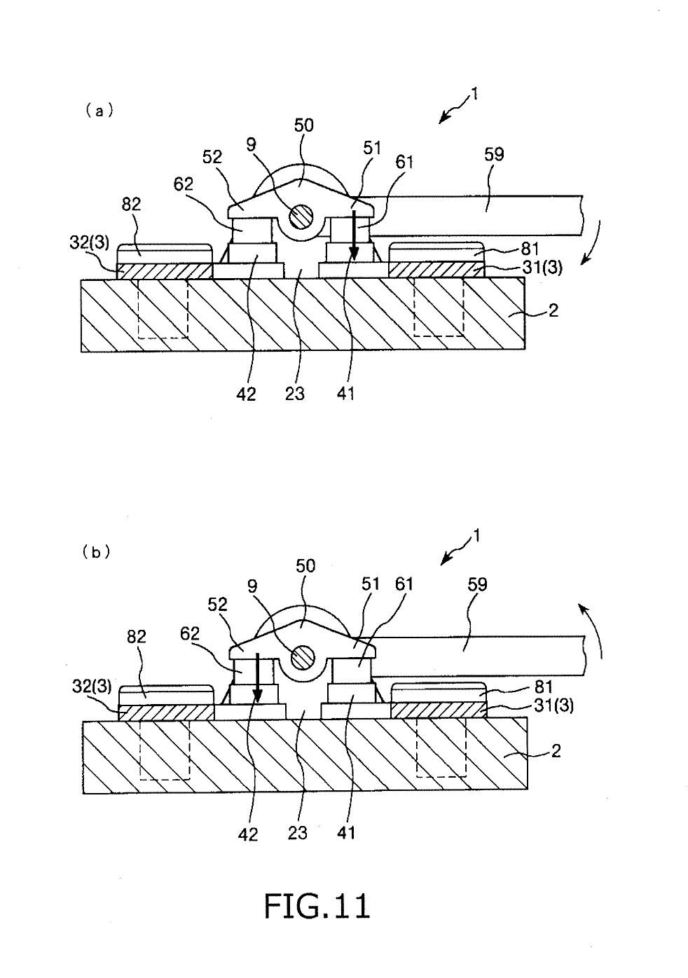

FIG. 10 is a perspective view showing the power generating element according to the second embodiment of the present invention. FIG. 11 is a cross-sectional view taken along a B-B line shown in FIG. 10.

Hereinafter, an upper side in each of FIGS. 10 and 11 is referred to as “upper” or “upper side” and a lower side in each of FIGS. 10 and 11 is referred to as “lower” or “lower side”. Further, a front side of the paper in each of FIGS. 10 and 11 is referred to as “front” or “front side” and a rear side of the paper in each of FIGS. 10 and 11 is referred to as “back” or “back side”. Furthermore, a right side in each of FIGS. 10 and 11 is referred to as “right” or “right side” and a left side in each of FIGS. 10 and 11 is referred to as “left” or “left side”.

Hereinafter, the power generating element according to the second embodiment will be described by placing emphasis on the points differing from the power generating element according to the first embodiment, with the same matters being omitted from description.

The power generating element 1 according to the second embodiment has the same configuration as the first embodiment except that the configuration of the pressing body 5 is modified. Namely, in the pressing body 5 of the second embodiment, a left end of the rod part 59 is connected to the back end surface of the central part 50 as shown in FIGS. 10 and 11.

Further, the left end of the rod part 59 is provided concentrically (coaxially) with the central part 50. Further, a through-hole into which the shaft 9 is inserted is formed through the left end of the rod part 59 and the central part 50. The rod part 59 is connected to the central part 50 so that the axial direction of the rod part 59 becomes substantially parallel to the upper surface of the base body 2. With such a configuration, it is possible to further reduce the height (thickness) of the power generating element 1.

An angle formed by the axial direction of the rod part 59 and the upper surface of the base body 2 is not limited to about 0° as shown in this embodiment and may be set to be any angle. Further, in the same manner as the first embodiment, the size, the shape and the weight of the rod part 59 may be appropriately adjusted. This makes it possible to further increase a degree of freedom in design of the power generating element 1.

In the power generating element 1 having such a configuration, when a right end (open end) of the rod part 59 is moved toward the lower side as shown in FIG. 11(a), that is, when the rod part 59 is pivotally moved around the shaft 9 in the lower direction, the pressing part 51 is moved toward the lower side and moved closer to the permanent magnet 41. Due to this movement, the magnetostrictive body 61 is compressed in the axial direction thereof by the pressing part 51 and the permanent magnet 41. As a result, the magnetic permeability of the magnetostrictive body 61 is varied due to the inverse magnetostrictive effect. This variation of the magnetic permeability of the magnetostrictive body 61 leads to the variation of the density of the lines of magnetic force passing through the magnetostrictive body 61 (the density of the lines of magnetic force passing through the inner cavity of the coil 7 in the axial direction thereof), and thereby generating the voltage in the coil 7. At this time, the pressing part 52 is moved in a direction leaving from the permanent magnet 42 (toward the upper side) together with the magnetostrictive body held (fixed) by the pressing part 52. However, the magnetostrictive body 62 is not pulled (stretched) so as to expand because the magnetostrictive body 62 is not fixed to the permanent magnet 42.

On the other hand, when the right end of the rod part 59 is moved toward the upper side as shown in FIG. 11(b), that is, when the rod part 59 is pivotally moved around the shaft 9 in the upper direction, the pressing part 52 is moved toward the lower side and moved closer to the permanent magnet 42. Due to this movement, the magnetostrictive body 62 is compressed in the axial direction thereof by the pressing part 52 and the permanent magnet 42. As a result, the magnetic permeability of the magnetostrictive body 62 is varied due to the inverse magnetostrictive effect. This variation of the magnetic permeability of the magnetostrictive body 62 leads to the variation of the density of the lines of magnetic force passing through the magnetostrictive body 62 (the density of the lines of magnetic force passing through the inner cavity of the coil 7 in the axial direction thereof), and thereby generating the voltage in the coil 7. At this time, the pressing part 51 is moved in a direction leaving from the permanent magnet 41 (toward the upper side) together with the magnetostrictive body held (fixed) by the pressing part 51. However, the magnetostrictive body 61 is not pulled (stretched) so as to expand because the magnetostrictive body 61 is not fixed to the permanent magnet 41.

The power generating element 1 according to the second embodiment can also provide the same functions/effects as the power generating element 1 according to the first embodiment.

### Third Embodiment

Next, description will be given to a power generating element according to a third embodiment of the present invention.

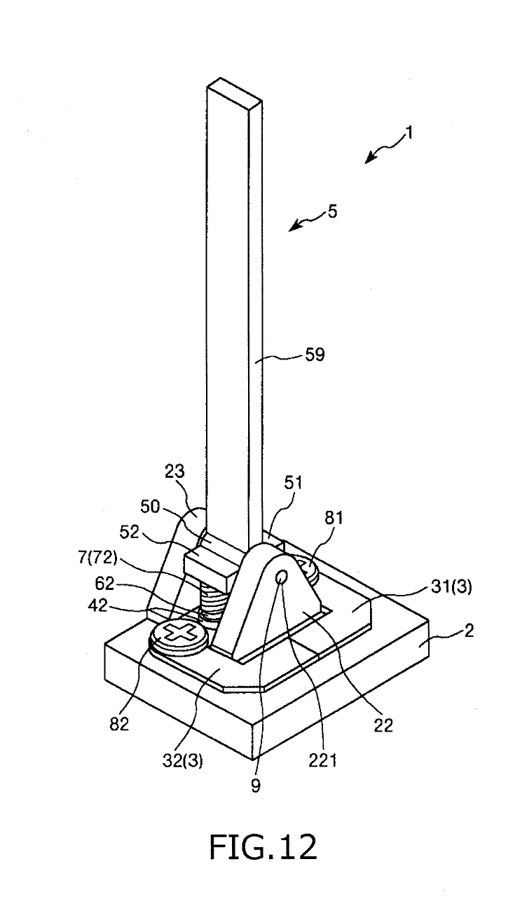

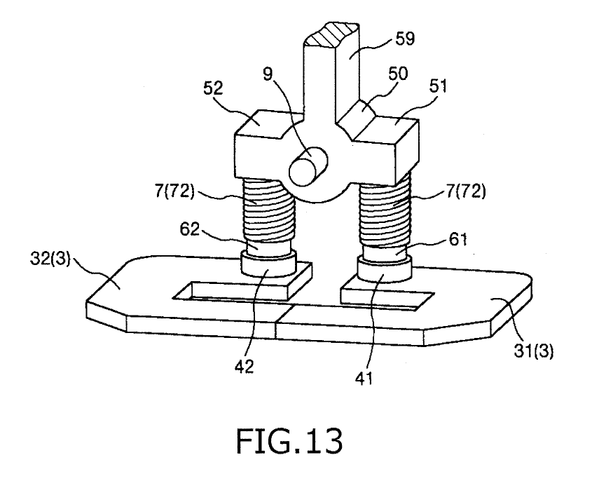

FIG. 12 is a perspective view showing the power generating element according to the third embodiment of the present invention. FIG. 13 is a perspective view showing the vicinity of a center of the power generating element shown in FIG. 12.

Hereinafter, an upper side in each of FIGS. 12 and 13 is referred to as “upper” or “upper side” and a lower side in each of FIGS. 12 and 13 is referred to as “lower” or “lower side”. Further, a front side of the paper in each of FIGS. 12 and 13 is referred to as “front” or “front side” and a rear side of the paper in each of FIGS. 12 and 13 is referred to as “back” or “back side”. Furthermore, a right side in each of FIGS. 12 and 13 is referred to as “right” or “right side” and a left side in each of FIGS. 12 and 13 is referred to as “left” or “left side”.

Hereinafter, the power generating element according to the third embodiment will be described by placing emphasis on the points differing from the power generating elements according to the first embodiment and the second embodiment, with the same matters being omitted from description.

The power generating element 1 according to the third embodiment has the same configuration as the first embodiment except that the arrangement position of the coil 7 is modified. Namely, in the power generating element 1 according to the third embodiment, two coils 7 are respectively provided on outer peripheral sides of the magnetostrictive bodies 61, 62 so as to surround the magnetostrictive bodies 61, 62. In this embodiment, each of the magnetostrictive bodies 61, 62 has an elongated cylindrical shape (having a large thickness) and each of the coils 7 is constituted by winding the wire 72 on the outer peripheral surfaces of the magnetostrictive bodies 61, 62.

In regions just above the permanent magnets 41, 42, the density of the lines of magnetic force (magnetic flux density) becomes highest and the variation amount of the lines of magnetic force becomes large. Thus, by respectively arranging the coils 7 on the outer peripheral sides of the magnetostrictive bodies 61, 62 located in the regions, it is possible to further improve the power generating efficiency of the power generating element 1.

In this embodiment, the length (thickness) of each of the magnetostrictive bodies 61, 62 is not particularly limited to a specific value, but is preferably in the range of about 1 to 8 mm, and more preferably in the range of about 2 to 5 mm. By setting the length of each of the magnetostrictive bodies 61, 62 to fall within the above range, it is possible to prevent mechanical strength of each of the magnetostrictive bodies 61, 62 from significantly deteriorating and cause uniform compressive stress in each of the magnetostrictive bodies 61, 62.

In the same manner as the first embodiment and the second embodiment, the coils 7 may be constituted of the bobbins 71 respectively provided on the outer peripheral sides of the magnetostrictive bodies 61, 62 so as to surround the magnetostrictive bodies 61, 62 and the wires 72 respectively wounded around the bobbins 71.

The power generating element 1 according to the third embodiment can also provide the same functions/effects as the power generating elements 1 according to the first embodiment and the second embodiment.

### Fourth Embodiment

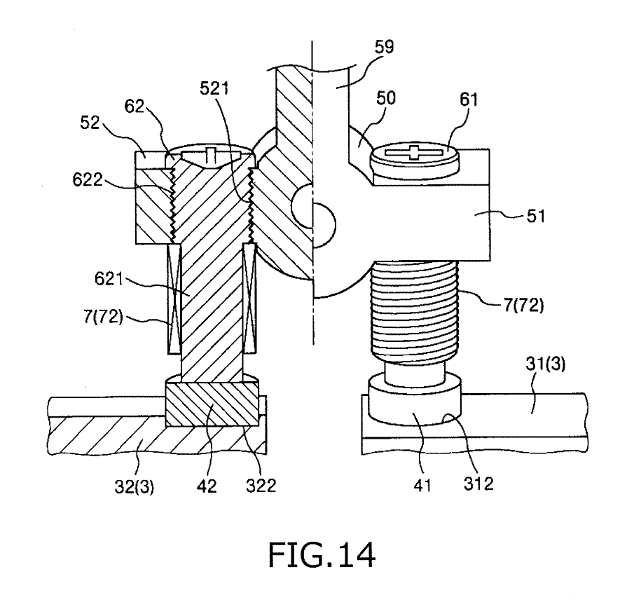

Next, description will be given to a power generating element according to a fourth embodiment of the present invention. FIG. 14 is an enlarged partial cross-sectional view showing the vicinity of a center of the power generating element according to the fourth embodiment of the present invention.

Hereinafter, an upper side in FIG. 14 is referred to as “upper” or “upper side” and a lower side in FIG. 14 is referred to as “lower” or “lower side”. Further, a front side of the paper in FIG. 14 is referred to as “front” or “front side” and a rear side of the paper in FIG. 14 is referred to as “back” or “back side”. Furthermore, a right side in FIG. 14 is referred to as “right” or “right side” and a left side in FIG. 14 is referred to as “left” or “left side”.

Hereinafter, the power generating element according to the fourth embodiment will be described by placing emphasis on the points differing from the power generating elements according to the first embodiment to the third embodiment, with the same matters omitted from description.

The power generating element 1 according to the fourth embodiment has the same configuration as the third embodiment except that the configuration of the holding structure for allowing the pressing part to hold the magnetostrictive body is modified.

As shown in FIG. 14, the magnetostrictive body 62 has a small-diameter part 621 on which the wire 72 of the coil 7 is wound and a threaded part 622 located on an upper side of the small-diameter part 621 and having a larger diameter than the small-diameter part 621. A threaded hole 521 into which the threaded part 622 of the magnetostrictive body 62 is screwed is formed in the pressing part 52 so as to pass through the pressing part 52 in the thickness direction of the pressing part 52. By passing the small-diameter part 621 through the threaded hole 521 and screwing the threaded part 622 into the threaded hole 521, the magnetostrictive body 62 is held (fixed) to the pressing part 52. Namely, in this embodiment, the holding structure for allowing the pressing part to hold the magnetostrictive body 62 is constituted of the threaded part 622 and the threaded hole 521.

Further, the magnetostrictive body 61 and the pressing part 51 have the same configurations as the magnetostrictive body 62 and the pressing part 52.

With such a configuration, even in a case where the base body 2, the yoke 3, the magnetostrictive bodies 61, 62 or the pressing body 5 is deflected when unwanted external force is applied to the power generating element 1, it is possible to stably fix the magnetostrictive bodies 61, 62 to the pressing body 5 (pressing parts 51, 52).

Further, by setting a maximum outer diameter of the coil 7 to be smaller than a minimum outer diameter of the threaded hole 521, it is possible to fix the magnetostrictive body 62 to the pressing part 52 by inserting the magnetostrictive body 62 having the coil 7, which is prepared by winding the wire 72 on an outer peripheral of the small-diameter part 621, into the threaded hole 521 and screwing the threaded part 622 into the threaded hole 521. This makes it possible to further reduce the time and effort for assembling the power generating element 1.

Further, by adjusting a screwing depth of the threaded part 622 to the threaded hole 521, it is possible to adjust a distance between the lower end of the magnetostrictive body 62 and the permanent magnet 42. This makes it possible to arbitrarily set the density of the lines of magnetic force passing through the magnetostrictive body 62. Furthermore, it is possible to prevent a backlash of the pressing body 5 with respect to the base body 2 by, for example, fixing (bonding) the magnetostrictive body 62 to the pressing part 52 or fixing (bonding) the central part 50 to the shaft 9 in a state that the lower end of the magnetostrictive body 62 contacts with the permanent magnet 42. This makes it possible to reliably prevent a trouble in that the magnetostrictive body 62 is not compressed because of the backlash of the pressing body 5 and the like.

The threaded part 622 of the magnetostrictive body 62 may be constituted of a large-diameter part obtained by merely enlarging the diameter of the small-diameter part 621. Namely, the threaded part 622 of the magnetostrictive body 62 may be constituted of a large-diameter part having no thread grooves and no thread ridges on an outer peripheral surface thereof. In this case, it is possible to fix the magnetostrictive body 62 to the pressing part 52 by forming a relatively small through-hole having an inner diameter slightly smaller than an outer diameter of the large-diameter part of the magnetostrictive body 62 on the pressing part 52 as substitute for the threaded hole 521 and engaging (fitting) the large-diameter part with the pressing part 52.

Further, thread grooves (or thread ridges) may be formed on an outer peripheral surface of the small-diameter part 621 of the magnetostrictive body 62. Namely, the thread grooves (or the thread ridges) may be formed along the entire of the magnetostrictive body 62. In this case, it becomes easy to wind the wire 72 constituting the coil 7 on the small-diameter part 621 and reliably hold the coil 7 on the small-diameter part 621.

The power generating element 1 according to the fourth embodiment can also provide the same functions/effects as the power generating elements 1 according to the first embodiment to the third embodiment.

### Fifth Embodiment

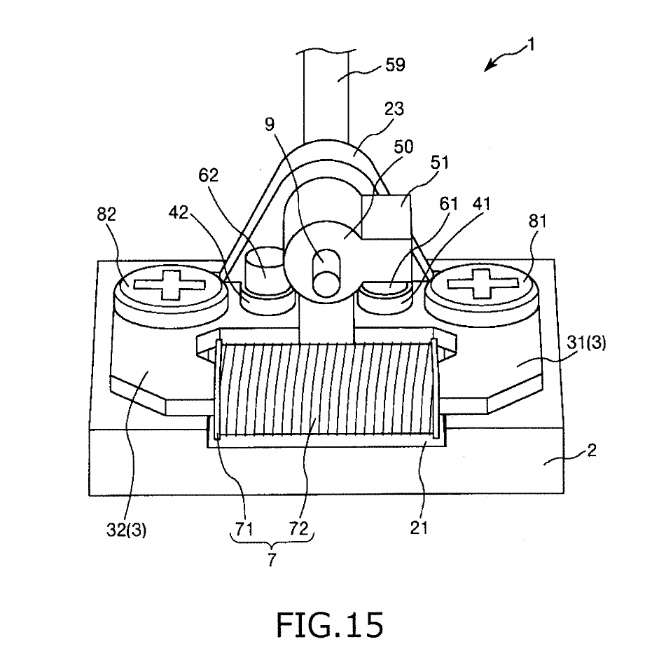

Next, description will be given to a power generating element according to a fifth embodiment of the present invention. FIG. 15 is a perspective view showing the vicinity of a center of the power generating element according to the fifth embodiment of the present invention.

Hereinafter, an upper side in FIG. 15 is referred to as “upper” or “upper side” and a lower side in FIG. 15 is referred to as “lower” or “lower side”. Further, a front side of the paper in FIG. 15 is referred to as “front” or “front side” and a rear side of the paper in FIG. 15 is referred to as “back” or “back side”. Furthermore, a right side in FIG. 15 is referred to as “right” or “right side” and a left side in FIG. 15 is referred to as “left” or “left side”.

Hereinafter, the power generating element according to the fifth embodiment will be described by placing emphasis on the points differing from the power generating elements according to the first embodiment to the fourth embodiment, with the same matters being omitted from description.

The power generating element 1 according to the fifth embodiment has the same configuration as the first embodiment except that the configuration of the pressing body is modified. Namely, in the pressing body 5 according to the fifth embodiment, the pressing part 52 is omitted and the left end of the rod part 59 is connected to the shaft 9 on the back side (opposite side) of the central part 50 through the bearing 23. The central part 50 is provided so as to contact with each of the magnetostrictive bodies 61, 62 or to be separated from each of the magnetostrictive bodies 61, 62 by a distance where the magnetic field loop is not broken.

With such a configuration, by pivotally moving the rod part 59 by about 180°, it is possible to alternately press and compress the magnetostrictive bodies 61, 62 in the axial direction thereof with one pressing part 51.

The power generating element 1 according to the fifth embodiment of the present invention can also provide the same functions/effects as the power generating elements 1 according to the first embodiment to the fourth embodiment.

### Sixth Embodiment

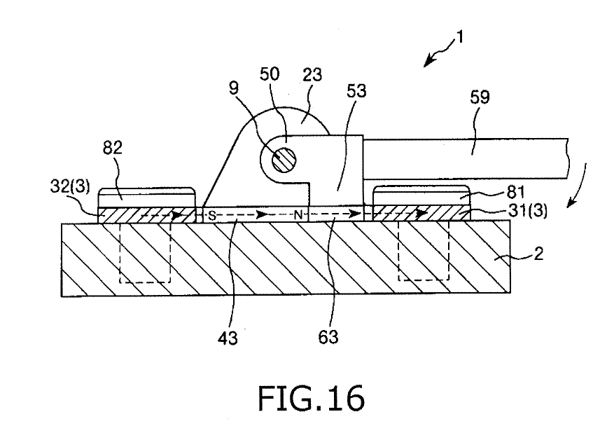

Next, description will be given to a power generating element according to a sixth embodiment of the present invention. FIG. 16 is a cross-sectional view showing the vicinity of a center of the power generating element according to the sixth embodiment of the present invention.

Hereinafter, an upper side in FIG. 16 is referred to as “upper” or “upper side” and a lower side in FIG. 16 is referred to as “lower” or “lower side”. Further, a front side of the paper in FIG. 16 is referred to as “front” or “front side” and a rear side of the paper in FIG. 16 is referred to as “back” or “back side”. Furthermore, a right side in FIG. 16 is referred to as “right” or “right side” and a left side in FIG. 16 is referred to as “left” or “left side”.

Hereinafter, the power generating element according to the sixth embodiment will be described by placing emphasis on the points differing from the power generating elements according to the first embodiment to the fifth embodiment, with the same matters being omitted from description.

The power generating element 1 according to the sixth embodiment has the same configuration as the second embodiment except that the configurations of the permanent magnet 41, the pressing body 5 and the magnetostrictive body 61 are modified.

In the power generating element 1 shown in FIG. 16, a plate-like permanent magnet 43 is further provided between the right side piece 31 and the left side piece 32 constituting the yoke 3 so as to contact with the other end of the left side piece 32. Further, a plate-like magnetostrictive body 63 is provided between the permanent magnet 43 and the right side piece 31 so as to contact with both the permanent magnet 43 and the other end of the right side piece 31. Furthermore, the magnetostrictive body 63 is arranged so that an easy magnetization direction of the magnetostrictive body 63 becomes the right-left direction (axial direction) of the magnetostrictive body 63. The clockwise magnetic field loop is also formed in the power generating element 1 as described above. In this embodiment, since the lines of magnetic force forming the magnetic field loop do not pass through the pressing body 5, it is possible to form the entire of the pressing body 5 with a nonmagnetic material.

Further, the pressing body 5 has one pressing part 53 provided so as to laterally and downwardly protrude from the central part 50. When the pressing part 53 is pivotally moved, the pressing part 53 compresses the magnetostrictive body 63 in a direction (vertical direction) substantially perpendicular to the axial direction thereof. Due to this compression, the magnetostrictive body 63 is expanded in the axial direction thereof. At this time, the magnetic permeability of the magnetostrictive body 63 is varied due to the inverse magnetostrictive effect. This variation of the magnetic permeability of the magnetostrictive body 63 leads to the variation of the lines of magnetic force passing through the magnetostrictive body 63 (the density of the lines of magnetic force passing through the inner cavity of the coil 7), and thereby generating the voltage in the coil 7.

The power generating element 1 according to the sixth embodiment can also provide the same functions/effects as the power generating elements 1 according to the first embodiment to the fifth embodiment.

The power generating element as described above can be applied to a power supply for a transmitter, a power supply for a sensor network, a wireless switch for house lighting, a system for monitoring status of each component of vehicle (for example, a tire pressure sensor and a sensor for seat belt wearing detection), a home security system (in particular, a system for wirelessly informing detection of operation to a window or a door) or the like.

Although the power generating elements of the present invention have been described with reference to the accompanying drawings, the present invention is not limited thereto. In the power generating element, the configuration of each component may be possibly replaced by other arbitrary configurations having equivalent functions. It may also be possible to add other optional components to the present invention. For example, it may also be possible to combine the configurations according to the first embodiment to the sixth embodiment of the present invention in an appropriate manner.

Further, one of the two magnets can be omitted and one or both of the two magnets can be replaced by electromagnets. Furthermore, the power generating element of the present invention can omit the two magnets and generate electric power by using external magnetic field.

In the first embodiment to the fifth embodiment, although the magnetostrictive body has the circular horizontal cross-sectional shape (cross-sectional shape in a direction substantially perpendicular to the axial direction thereof), the present invention is not limited thereto. Examples of the horizontal cross-sectional shape of the magnetostrictive body include an ellipse shape and a polygonal shape such as a triangular shape, a square shape, a rectangular shape and a hexagonal.

### INDUSTRIAL APPLICABILITY

According to the present invention, it becomes unnecessary to strongly connect the components of the power generating element with each other because the power generating element can generate electric power only by compressing the magnetostrictive body. Thus, it is possible to provide the power generating element which has the relatively simple configuration and can efficiently generate electric power. For the reasons stated above, the present invention is industrially applicable.

### DESCRIPTION OF REFERENCE NUMBER

1 . . . power generating element; 2 . . . base body; 21 . . . concave portion; 22, 23 . . . bearing; 221, 231 . . . through-hole; 241, 242 . . . threaded hole, 3 . . . yoke; 31 . . . right side portion; 32 . . . left side portion; 311, 321 . . . through-hole; 312, 322 . . . concave portion; 41, 42, 43 . . . permanent magnet; 5 . . . pressing body; 50 . . . central part; 51, 52, 53 . . . pressing part; 511 . . . rib; 521 . . . threaded hole; 59 . . . rod part; 61, 62, 63 . . . magnetostrictive body; 621 . . . small-diameter part; 622 . . . threaded part; 7 . . . coil; 71 . . . bobbin; 72 . . . wire; 81, 82 . . . screw; 9 . . . shaft

1. A power generating element comprising:
at least one pillar-shaped magnetostrictive body through which lines of magnetic force pass in an axial direction thereof, the at least one magnetostrictive body formed of a magnetostrictive material;
a pressing body having a pressing part provided so as to press the magnetostrictive body when the pressing part is pivotally moved and a rod part for pivotally moving the pressing part; and
a coil provided so that the lines of magnetic force pass through the coil in an axial direction thereof and in which a voltage is generated on the basis of a variation of density of the lines of magnetic force,
wherein the power generating element is configured to vary the density of the lines of magnetic force when the pressing part is pivotally moved due to a pivotal movement of the rod part around a pivotal center and then the magnetostrictive body is pressed and compressed by the pressing part.

2. The power generating element as claimed in claim 1, wherein the pressing body has a central part which can be pivotally moved around the pivotal center, and
wherein the pressing part is provided on an area of the central part so as to laterally protrude from the central part, and the rod part is connected with the central part at another area differing from the area of the central part on which the pressing part is provided.

3. The power generating element as claimed in claim 1, wherein the pressing part has a holding structure for holding the magnetostrictive body.

4. The power generating element as claimed in claim 1, wherein the at least one magnetostrictive body includes two magnetostrictive bodies respectively provided on both sides of the central part so that the two magnetostrictive bodies are alternately pressed by the pressing part.

5. The power generating element as claimed in claim 1, wherein the coil is provided on an outer peripheral side of the magnetostrictive body so as to surround the magnetostrictive body.

6. The power generating element as claimed in claim 1, wherein the magnetostrictive material contains an iron-gallium based alloy as a major component thereof.

7. The power generating element as claimed in claim 1, wherein a Young's modulus of the magnetostrictive material is in the range of 40 to 100 GPa.

8. The power generating element as claimed in claim 1, wherein the pressing part is formed of a magnetic material and provided so as to press the magnetostrictive body in the axial direction of the magnetostrictive body.

9. The power generating element claimed in claim 8, further comprising:
a magnet for generating the lines of magnetic force; and
a loop forming body for forming a loop in cooperation with at least the magnetostrictive body and the pressing part so that the lines of magnetic force generated from the magnet flow in the loop and return to the magnet, the loop forming body formed of a magnetic material.

10. The power generating element as claimed in claim 9, wherein the coil is provided in a middle of the loop forming body so as to surround the loop forming body.

11. The power generating element as claimed in claim 9, wherein the magnet is provided between the magnetostrictive body and the loop forming body.

12. The power generating element as claimed in claim 9, wherein the loop forming body has a holding structure for holding the magnet.
